(19) United States
(12) Patent Application Publication
(10) Pub. No.: US 2012/0103388 A1
(43) Pub. Date: May 3, 2012

(54) MONOLITHIC MODULE ASSEMBLY USING BACK CONTACT SOLAR CELLS AND METAL RIBBON

(75) Inventors: David H. Meakin, Albuquerque, NM (US); Fares Bagh, Austin, TX (US); James Gee, Albuquerque, NM (US); William Bottenberg, Boulder Creek, CA (US)

(73) Assignee: APPLIED MATERIALS, INC., Santa Clara, CA (US)

(21) Appl. No.: 13/284,784

(22) Filed: Oct. 28, 2011

Related U.S. Application Data
(60) Provisional application No. 61/408,464, filed on Oct. 29, 2010.

(51) Int. Cl. H01L 31/05; H01L 31/048; H01L 31/18; H01L 31/0216

(52) U.S. Cl. 136/244; 136/256; 156/299; 156/300; 156/250; 156/256; 438/66; 257/E31.119

(57) ABSTRACT

Embodiments of the invention contemplate the formation of a solar cell module comprising an array of interconnected solar cells that are formed using an automated processing sequence that is used to form a novel planar solar cell interconnect structure. In one embodiment, the module structure described herein includes a patterned adhesive layer that is disposed on a backsheet to receive and bond a plurality of conducting ribbons thereon. The substantially planar bonded conducting ribbons are then used to interconnect an array of solar cell devices to form a solar cell module that can be electrically connected to one or more external components, such as an electrical power grid, satellites, electronic devices or other similar power requiring units. Embodiments of the invention may further provide a roll-to-roll system that is configured to serially form a plurality of solar cell modules over different portions of a backsheet material received from a roll of backsheet material.

### CROSS-REFERENCE TO RELATED APPLICATIONS

This application claims priority benefit to U.S. Provisional Patent Application titled, Ser. No. 61/408,464, and entitled “Monolithic Module Assembly Using Back Contact Solar Cells and Metal Ribbon,” filed Oct. 29, 2010, which is herein incorporated by reference.

### BACKGROUND OF THE INVENTION

1. Field of the Invention

The present invention relates to an array of interconnected solar cells that are used to form a photovoltaic module.

2. Description of the Related Art

Solar cells are photovoltaic devices that convert sunlight directly into electrical power. Each solar cell generates a specific amount of electric power and is typically tiled into an array of interconnected solar cells, or modules, that are sized to deliver a desired amount of generated electrical power. The most common solar cell base material is silicon, which is in the form of single crystal or multicrystalline substrates, sometimes referred to as wafers. Because the amortized cost of forming silicon-based solar cells to generate electricity is higher than the cost of generating electricity using traditional methods, there has been an effort to reduce the cost to form solar cells and the solar cell modules in which they are housed to generate electricity.

The typical fabrication sequence of photovoltaic modules using silicon solar cells includes the formation of the solar cell circuit, assembly of the layered structure (glass, polymer, solar cell circuit, polymer, backsheet), and then lamination of the layered structure. The final steps include installation of the module frame and junction box, and testing of module. The solar cell circuit is typically made with automated tools (“stringer/tabbers”) that electrically connect the solar cells in series using copper (Cu) flat ribbon wires (“interconnects”). Several strings of series-connected solar cells are then electrically connected with wide copper ribbons (“busses”) to complete the circuit. These busses also bring the current to the junction box from several points in the circuit for the bypass diodes and for connection to the junction box cables.

One type of solar cell is a back-contact solar cell, or all back contact solar cell device. Back-contact solar cells have both the negative-polarity and positive-polarity contacts on the back surface of the formed solar cell device. Location of both polarity contacts on the same surface simplifies the electrical interconnection of the solar cells, and also opens the possibility of new assembly approaches and new module designs. The phrase “Monolithic module assembly” refers to a process of connecting the solar cell and the photovoltaic laminate in the same step and has been previously described (see, U.S. Pat. Nos. 5,951,786 and 5,972,732, and J. M. Gee, S. E. Garrett, and W P. Morgan, Simplified module assembly using back-contact crystalline-silicon silicon cells, 26^{th} IEEE Photovoltaic Specialists Conference, Anaheim, Calif., 29 Sep.-3 Oct. 1997). The monolithic module assembly starts with a backsheet that has a patterned electrical conductor layer formed thereon. Production of such patterned conductor layers on flexible large-area substrates is well known from printed-circuit board and flexible-circuit industries. The back-contact cells are placed on this backsheet with pick-and-place tools, which are well known in the art. The solar cells are electrically connected to the patterned electrical conductor layer disposed on the backsheet during a lamination step, thereby making the laminated package and electrical circuit in a single step and with simple automation. The laminated package comprises materials such as solders or conductive adhesives that form the electrical connection during the lamination process. The backsheet may optionally comprise an electrical insulator layer to prevent shorting of the electrical conductors on the backsheet with the conductors on the solar cell.

This conventional photovoltaic module design and assembly approaches discussed above are well known in the industry, and have the following disadvantages. First, the process of electrically connecting solar cells in series is difficult to automate so that stringer/tabbers have limited throughput and are expensive. Second, interconnects contained in the assembled solar cell circuit, which are formed between each of the solar cells in the array of solar cells, are typically unsupported and are very fragile prior to encapsulation in the lamination step. Third, the stiffness of the copper (Cu) ribbon interconnect must be minimized to avoid stressing the fragile silicon solar cell. Hence, due to the electrical connection configuration it is often required that the thickness of the interconnect be reduced to a point where the resistance of the copper interconnect is high enough to increase the electrical losses and affect solar cell performance. Fourth, the use of interconnected and stiff copper ribbons is difficult to use in conjunction with thin crystalline-silicon solar cells, which as the industry advances continue to get thinner to reduce the solar cell cost and improve performance. Fifth, the spacing between solar cells must be large enough to accommodate stress relief for the copper interconnect wires, which reduces the module efficiency due to the non-utilized space between the solar cells. This is particularly true when using silicon solar cells with positive and negative polarity contacts on opposite surfaces. Finally, conventional processes of forming solar cell modules using the methods described above are complicated multistep labor intensive processes that add to the cost required to complete the solar cells.

Therefore, there exists a need for improved methods and apparatus to form an interconnection between the active and current carrying regions formed on an array of interconnected solar cells.

### SUMMARY OF THE INVENTION

The present invention generally provides a backsheet that can be used in a solar cell module assembly, comprising a flexible backsheet having a mounting surface, a patterned adhesive layer comprising a plurality of adhesive regions that are disposed on the mounting surface, and a plurality of conducting ribbons, wherein a first surface of each of the conducting ribbons is disposed on at least one of the plurality of adhesive regions, and each of the plurality of conducting ribbons are substantially planar and are non-linear relative to a plane that is substantially parallel to the mounting surface.

Embodiments of the present invention may also provide a method of forming a solar cell device, comprising positioning a plurality of conducting ribbons over a mounting surface of a flexible backsheet, wherein an adhesive region is disposed between the mounting surface and a first surface of each of the plurality of conducting ribbons, and each of the plurality of conducting ribbons are substantially planar and are non-linear relative to a plane that is substantially parallel to the mounting surface.

Embodiments of the present invention may also provide a method of forming a solar cell device, comprising depositing a conductive material on a plurality of planar shaped conducting ribbons that are disposed on a portion of a flexible backsheet that is disposed in a first processing region of a system, wherein the conductive material is disposed on one or more conductive material regions on a first surface of each of the plurality of planar shaped conducting ribbons, transferring the portion of the flexible backsheet to a second processing region of the system that is downstream of the first processing region, positioning a plurality of solar cells over the deposited conductive material to form an array of interconnected solar cells in the second processing region of the system, wherein an active portion of each positioned solar cell is in electrical communication with one of the one or more conductive material regions and one of the plurality of planar shaped conducting ribbons, positioning an encapsulant material over the array of interconnected solar cells disposed over the portion of the backsheet, positioning a protective sheet over the encapsulant material, heating the portion of the backsheet material, plurality of planar shaped conducting ribbons, encapsulant material and protective sheet to form a bond therebetween in a third processing region of the system that is downstream of the second processing region, and cutting a portion of the flexible backsheet material to separate the portion of the flexible backsheet material from other portions of the flexible backsheet material.

Embodiments of the present invention may also provide a solar cell module, comprising a backsheet having a mounting surface, a patterned adhesive layer comprising a plurality of adhesive regions that are disposed on the mounting surface, a plurality of conducting ribbons that are disposed over the adhesive regions, and a plurality of solar cells that are disposed over the conducting ribbons to form an interconnected solar cell array, wherein each of the plurality of solar cells is electrically connected to a portion of a conducting ribbon by use of a conductive material, and the array is formed of the cells by the conducting ribbons.

Embodiments of the present invention may also provide a method of forming a solar cell device, comprising depositing a patterned adhesive layer on a mounting surface of a backsheet, wherein the patterned adhesive layer forms a plurality of adhesive regions on the mounting surface, disposing a conducting ribbon over each of the formed adhesive regions, depositing a conductive material on the conducting ribbon, and disposing a plurality of solar cells over the conductive material disposed to form an interconnected solar cell array.

Embodiments of the present invention may also provide a method of forming a solar cell device, comprising disposing a portion of a backsheet in a first processing region, wherein the portion of the backsheet is coupled to a roll of backsheet material, positioning plurality of conducting ribbons over the portion of the backsheet that is disposed in the first processing region, wherein an adhesive region is disposed between the portion of the backsheet and a first surface of each of the plurality of conducting ribbons, depositing a conductive material on a second surface of the conducting ribbons in a second processing region that is downstream of the first processing region, wherein the deposited conductive material comprises one or more conductive material regions disposed on each of the conducting ribbons, positioning a plurality of solar cells over the deposited conductive material to form an array of interconnected solar cells in a third processing region that is downstream of the second processing region, wherein an active portion of each positioned solar cell is in electrical communication with a conductive material region and the conducting ribbon, positioning an encapsulant material over the array of interconnected solar cells disposed on the portion of the backsheet, wherein the positioning of an encapsulant material is performed in a fourth processing region that is downstream of the third processing region, positioning a protective sheet, such as a glass sheet, over the encapsulant material, heating the portion of the backsheet material, patterned adhesive layer, conducting ribbons, encapsulant material and protective sheet to form a bond therebetween in a sixth processing region that is downstream of the fifth processing region, and cutting a portion of the backsheet material to separate the portion of the backsheet material from the other portions of the backsheet material.

Embodiments of the present invention may also provide a method of forming a solar cell device, comprising depositing a plurality of adhesive regions on a portion of a backsheet material which is coupled to a roll, positioning a first surface of a conducting ribbon on each of the deposited adhesive regions deposited on the portion of the backsheet material, depositing a conductive material on a second surface of the conducting ribbons, wherein the deposited conductive material comprises one or more conductive material regions disposed on each of the conducting ribbons, positioning a plurality of solar cells over the deposited conductive material to form an array of interconnected solar cells, wherein an active portion of each positioned solar cell is in electrical communication with a conductive material region and the conducting ribbon, positioning an encapsulant material and a protective sheet, such as a glass sheet, over the plurality of solar cells, heating the portion of the backsheet material, patterned adhesive layer, conducting ribbons, encapsulant material and protective sheet to form a bond therebetween, and cutting a portion of the backsheet material to separate the portion of the backsheet material from the other portions of the backsheet material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1A is a bottom view illustrating a solar cell module according to one embodiment of the invention.

FIG. 1B is a bottom view illustrating a solar cell module according to one embodiment of the invention.

FIGS. 2A-2F are schematic cross-sectional views that illustrate the various processing steps used to form a solar cell module according to one embodiment of the invention.

FIG. 2G is a schematic cross-sectional view that illustrates an alternate configuration of the solar cell module illustrated in FIG. 2E according to one embodiment of the invention.

FIG. 2H is a schematic cross-sectional view that illustrates an alternate configuration of the solar cell module illustrated in FIG. 2E according to one embodiment of the invention.

FIG. 3 illustrates processing steps used to form the solar cell module illustrated in FIGS. 2A-2F according to an embodiment of the invention.

FIG. 4 is a schematic view of a roll-to-roll system that is adapted to form a solar cell module according to an embodiment of the invention.

FIG. 5 illustrates processing steps used to form a solar cell module using the roll-to-roll system illustrated in FIG. 4 according to an embodiment of the invention.

For clarity, identical reference numerals have been used, where applicable, to designate identical elements that are common between figures. It is contemplated that features of one embodiment may be incorporated in other embodiments without further recitation.

### DETAILED DESCRIPTION

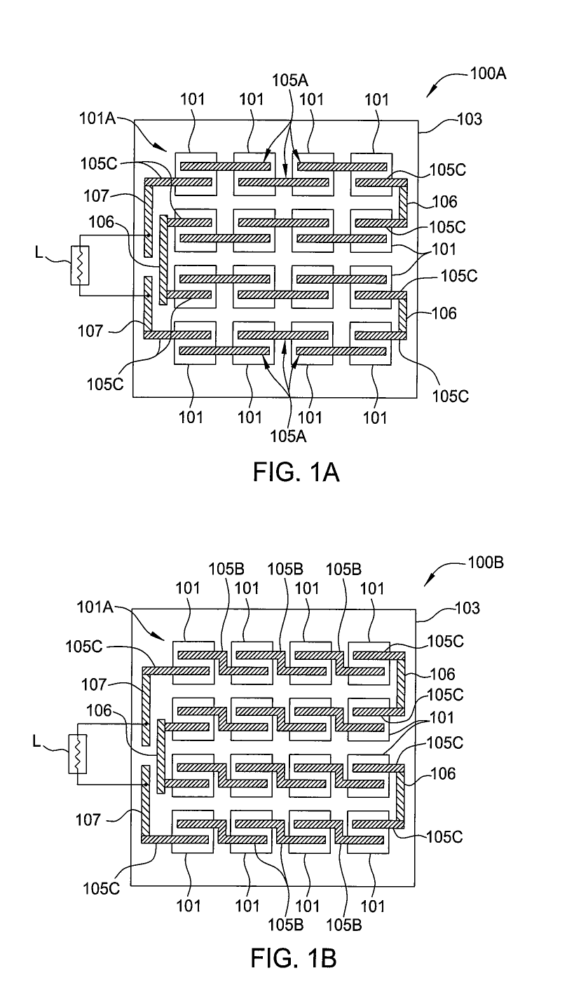

Embodiments of the invention contemplate the formation of a solar cell module assembly comprising an array of interconnected solar cells that are formed using an automated processing sequence that is used to form a novel planar solar cell interconnect structure. In one embodiment, the module structure described herein includes a patterned adhesive layer that is disposed on a backsheet to receive and bond a plurality of conducting ribbons thereon. The substantially planar bonded conducting ribbons are then used to interconnect an array of solar cell devices to form a solar cell module that can be electrically connected to external components that are adapted to receive the solar cell module's generated electricity. Typical external components, or external loads “L” (FIG. 1A-1B), may include an electrical power grid, satellites, electronic devices or other similar power requiring units. Solar cell structures that may benefit from the invention disclosed herein include back-contact solar cells, such as those in which both positive and negative contacts are formed only on the rear surface of the device. Solar cell devices that may benefit from the ideas disclosed herein may include devices containing materials, such as single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), as well as heterojunction cells, such as GaInP/GaAs/Ge, ZnSe/GaAs/Ge or other similar substrate materials that can be used to convert sunlight to electrical power. Embodiments of the invention can be useful for module designs that include thin crystalline solar cells, due in part to the planar design of the conducting ribbons that minimize or prevent stress from being transmitted to the thin solar cells positioned in the solar cell module.

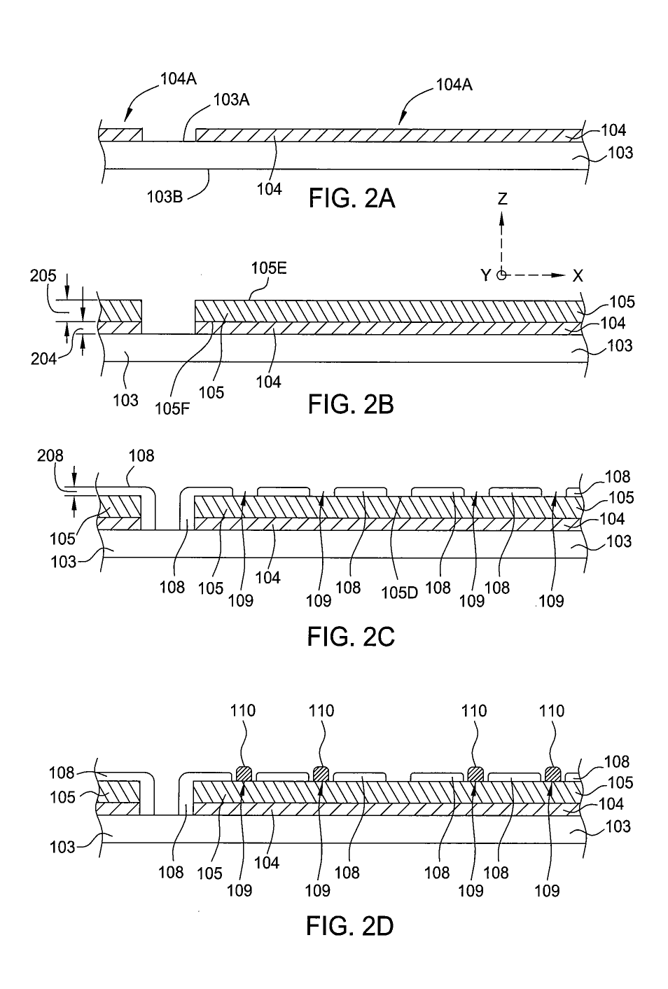

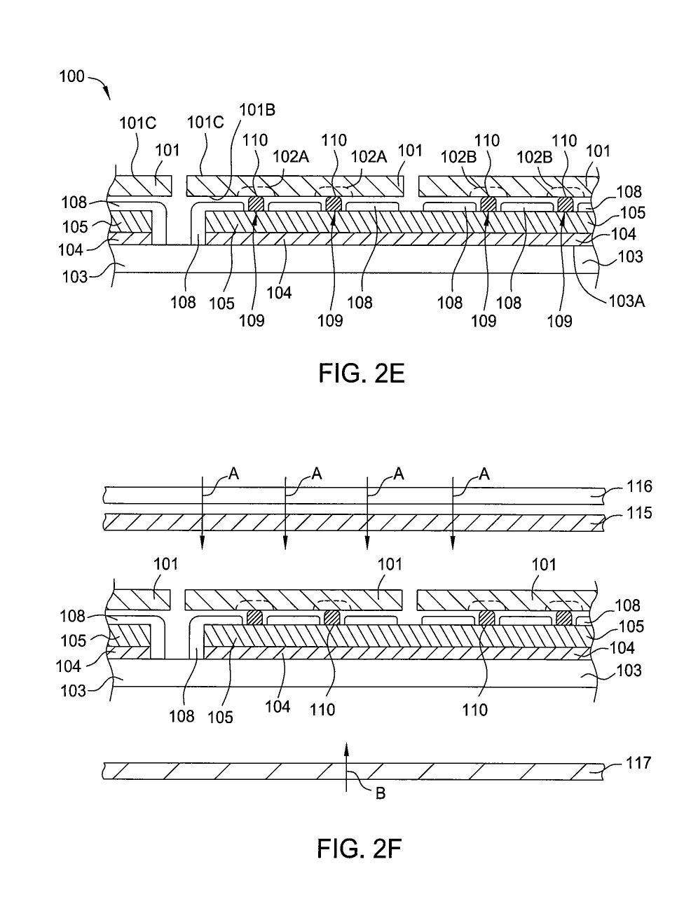

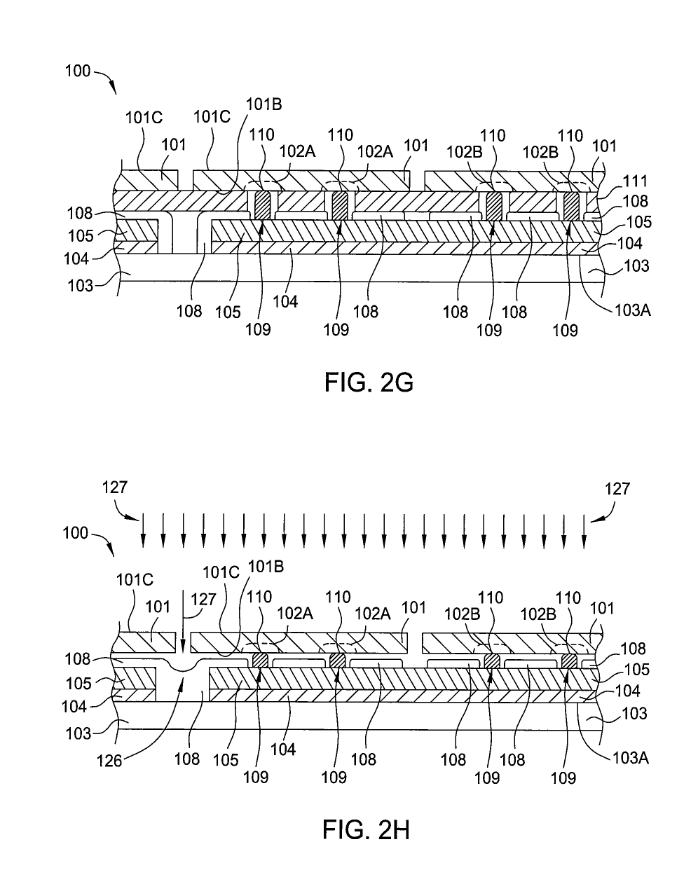

FIG. 1A is a bottom view of one embodiment of a solar cell module 100A, or solar cell module assembly, having an array of interconnected solar cells 101 disposed over a top surface 103A (FIG. 2E) of a backsheet 103, as viewed through the bottom surface 103B (FIG. 2A) of the backsheet 103. For clarity reasons, the backsheet 103 illustrated in FIG. 1A is schematically shown as being transparent to allow one to view the components in the solar cell module 100A, and is not intended to be limiting as to the scope of the invention described herein. In one embodiment, the solar cells 101 in the solar cell module 100A are back-contact type solar cells in which light received on a front surface 101C (FIG. 2E) of a solar cell 101 is converted into electrical energy. In general, the solar cells 101 in the solar cell array 101A are connected in a desired way by use of conducting ribbons, such as reference numerals 105A and 105C in FIGS. 1A, or reference numeral 105 in FIGS. 2B-2F. The term “conducting ribbon,” as used herein, may generally include any conductive element, such as a metal foil, metal sheet, conductive paste or other similarly configured conductive material that can be cut, stamped, folded, or machined to any desirable shape, size and/or thickness. In one example, the solar cells 101 in the solar cell array 101A are connected in series, such that the generated voltage of all the connected solar cells will add and the generated current remains relatively constant. In this configuration, the n-type and p-type regions formed in each interconnected solar cell are separately connected to regions formed in adjacent solar cells that have an opposing dopant type by use of the conducting ribbons 105A. One skilled in the art will appreciate that at the start and end of each row of the solar cell array 101A, conducting ribbons 105C and interconnects 106 can be used to join adjacent rows, and the interconnects 107 and conducting ribbons 105C, which are connected to solar cells 101 found at the start and end of the interconnected solar cell array 101A, can be used to connect the output of the solar cell array 101A to an external load “L”. In this configuration, for similarly configured solar cells 101, every other solar cell is rotated 180° in a plane parallel to the surface 103A of the backsheet 103, so that the n-type and p-type regions in adjacent cells will be aligned for easy connection using straight conducting ribbons 105A. One skilled in the art will appreciate that in some embodiments, the solar cells 101 can also be connected in parallel versus in series to limit the generated voltage, or increase the output current of the module.

FIG. 1B is a bottom view of one embodiment of a solar cell module 100B having an array of interconnected solar cells 101 disposed over a top surface 103A (FIG. 2E) of a backsheet 103, as viewed through the bottom surface 103B (FIG. 2A) of the backsheet 103. For clarity reasons, the backsheet 103 illustrated in FIG. 1B is schematically shown as being transparent to allow one to view the components in the solar cell module 100B, and is not intended to be limiting as to the scope of the invention described herein. In one embodiment, the solar cells 101 in the solar cell module 100B are back-contact type solar cells. As discussed above, the solar cell array 101A may be connected in a desired way by use of conducting ribbons, such as those shown by reference numerals 105B and 105C in FIG. 1B, or reference numeral 105 in FIGS. 2B-2F. In one embodiment, solar cells 101 in a solar cell array 101A are connected in series in such a way that the formed n-type and p-type regions formed in each interconnected solar cell are separately connected to regions formed in adjacent solar cells that have an opposing dopant type by use of conducting ribbons 105B. One skilled in the art will appreciate that at the start and end of each row of the solar cell array 101A, conducting ribbons 105C and interconnects 106 can be used to join adjacent rows, and the interconnects 107 and conducting ribbons 105C, which are connected to solar cells 101 found at the start and end of the interconnected solar cell array 101A, can be used to connect the output of the solar cell array 101A to an external load “L”. In this example, for similarly configured solar cells, each solar cell 101 is similarly oriented relative to the surface of the backsheet 103 so that the n-type and p-type regions in adjacent cells can be connected by use of a conducting ribbon 105B, and all of the solar cells 101 in each adjacent row of solar cells 101 are rotated 180° relative to each other, so that the orientation of the n-type and p-type regions of the solar cells in adjacent rows will be aligned to form a series connected solar cell module. In this configuration, the conducting ribbons 105B are shaped to connect the desired regions in adjacently positioned solar cells. In one embodiment, as shown in FIG. 1B, the conducting ribbons are s-shaped to allow for a simplified positioning, orientation and interconnection of the solar cells 101 in the solar cell module 100B. One will note that in yet another connection configuration example, the solar cells in all of the rows of solar cells are oriented similarly, but each of the conducting ribbons 105B in each adjacent row are rotated 180° relative to each other (e.g., adjacent rows of conducting ribbons are mirror images of each other) to provide a serially connected interconnected solar cell array.

In one embodiment of a solar cell module, the conducting ribbons 105B are substantially planar in a direction normal to the top surface 103A of the back sheet 103 (Z-direction), and are non-linear in a direction parallel to the top surface 103A of the back sheet 103, such as having an s-shape in the X-Y plane. The non-linear planar, or “flat” or non-curved in the Z-direction, shape of the conducting ribbons 105B will tend to reduce the stiffness of the conducting ribbons 105B, and thus reduce any stress induced into the interconnected solar cell array by the conducting ribbons 105B. The non-linear shape of the conducting ribbons 105B in the X-Y plane can reduce the stiffness of the conducting ribbons 105B, thus reducing or minimizing the induced stress in the solar cells 101 and at the electrical connection points by the conducting ribbons 105B during the formation of the solar cell module or during its use in the field, as further discussed below. The non-linear format also allows for wider selection of geometries for contacting the solar cell, which can help maximize the performance of the module while minimizing the cost of the solar cell. As noted above, in some configurations it may be desirable to connect at least some of the solar cells 101 in the solar cell module 100B in parallel versus in series. While the solar cell arrays 101A in FIGS. 1A-1B illustrate a four-by-four array of solar cells 101, this configuration is not intended to limiting as to the scope of the invention described herein. The flexible nature of the planar conducting ribbons 105B in the interconnecting structure in the formed solar cell module can reduce the stresses applied to the often thin solar cells 101 by the interconnects when wind and snow loads are applied to the solar cell module when it is in use in the field.

### Solar Cell Module Formation Processes

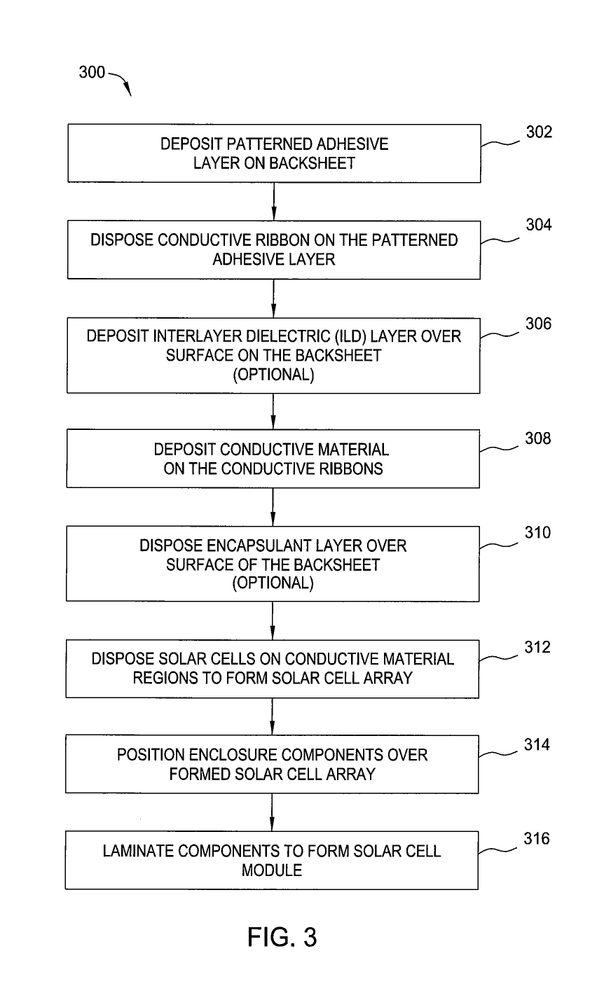

FIGS. 2A-2F are schematic cross-sectional views illustrating different stages of a processing sequence that are used to form a solar cell module 100. FIG. 3 illustrates a process sequence 300 used to form a solar cell module 100, similar to either of the solar cell modules 100A, 100B shown in FIGS. 1A and 1B. The sequence found in FIG. 3 corresponds to the stages depicted in FIGS. 2A-2F, which are discussed herein.

At step 302, and as shown in FIG. 2A, an adhesive material 104 is deposited in a desired pattern on the top surface 103A of a backsheet 103. In one embodiment, the adhesive material 104 is deposited on the top surface 103A in a desired pattern to form a plurality of discrete adhesive regions 104A. In one embodiment, the adhesive material disposed in the adhesive regions 104A are deposited in shape(s) that will be substantially covered by the conducting ribbons 105, which are placed thereon in a subsequent processing step. Since the patterned adhesive material 104 is covered by the conducting ribbons 105, the chance that the adhesive material will interact with the other solar cell module components (e.g., ILD material 108, solar cells 101) during the subsequent processing steps is reduced. The reduced interaction between the adhesive material and the other solar cell module components prevents any out-gassing of the adhesive material, or the adhesive properties of the adhesive material itself, from contaminating or attacking one or more of the components in the formed solar cell module and/or or affecting the solar cell module manufacturing processes and device yield.

In one embodiment, the adhesive material 104 is a low temperature curable adhesive (e.g., <180° C.) that doesn't significantly out-gas. In one embodiment, the adhesive material 104 is a pressure sensitive adhesive (PSA) that is applied to desired locations on the top surface 103A of the backsheet 103. The adhesive material 104 can be applied to the backsheet 103 using screen printing, stenciling, ink jet printing, rubber stamping or other useful application methods that provides for accurate placement of the adhesive material in the desired locations on the backsheet 103. In one embodiment, the adhesive material 104 is a UV curable pressure sensitive adhesive (PSA) material that can be at least partially cured by the application of UV light during step 302. The use of a UV curable PSA material has advantages over other thermally activated adhesive materials, since the adhesive material and backsheet 103 do not need to be heated to a controlled temperature to form an adequate bond between the conducting ribbon 105 and backsheet 103, and thus reducing any induced thermal stress in the solar cell module components and reducing the system complexity. The use of UV curable adhesives also allows the adhesive to be rapidly partially cured after deposition to assure that the adhesive material is physically stable and/or somewhat “tacky” during the subsequent processing steps. In one example, the adhesive material 104 is a UV curable PSA material that has a thickness 204 (FIG. 2B) of between about 5 μm thick and about 200 μm thick. In one example, the adhesive material 104 is a UV curable PSA material that has a thickness 204 of between about 15 μm thick and about 20 μm thick. In another embodiment, the conductive interconnect is coated prior to assembly with the adhesive. In some embodiments, the printing and curing of the adhesive material 104 can be done on a backsheet that is formed to allow for a continuous roll-to-roll process. In other embodiments, the adhesive material 104 could also be applied to backsheets 103 that have been cut to a desirable size prior to the application of the adhesive material 104.

In one embodiment, the backsheet 103 comprises a 100-350 μm thick composite of polymeric materials, such as polyethylene terephthalate (PET), polyvinyl fluoride (PVF), polyester, polyimide, or polyvinylidene fluoride (PVDF), ethylene vinyl acteate (EVA) or polyolefin. In one example, the backsheet 103 is a 100-350 μm thick sheet of polyethylene terephthalate (PET). In another embodiment, the backsheet 103 comprises one or more layers of material that include one or more layers of polymeric materials and/or one or more layers of a metal (e.g., aluminum). In one example, the backsheet 103 comprises a 150 μm polyethylene terephthalate (PET) sheet, a 25 μm thick sheet of polyvinyl fluoride that is purchased under the trade name DuPont 2111 Tedlar™, and a thin aluminum layer. It should be noted that the bottom surface 103B of the backsheet 103 will generally face the environment, and thus portions of the backsheet 103 may be configured to act as a UV and/or vapor barrier. Thus, the backsheet 103 is generally selected for its excellent mechanical properties and ability to maintain its properties under long term exposure to UV radiation. A PET layer may be selected because of its excellent long term mechanical stability and electrical isolative properties. The backsheet, as a whole, is preferably certified to meet the IEC and UL requirements for use in a photovoltaic module.

Next, at step 304, and as shown in FIG. 2B, the conducting ribbons 105 are cut to a desired shape and/or length, and placed on the patterned adhesive material 104. The process of placing the conducting ribbons 105 on the adhesive material, may include applying pressure to the conducting ribbons 105 to assure that they are sufficiently affixed to the backsheet 103. In one embodiment, a surface 105F of the conducting ribbons 105 is substantially affixed to the top surface 103A of the backsheet 103 via the adhesive material 104, thus allowing the conducting ribbons 105 to remain in a substantially planar orientation (e.g., parallel to X-Y plane) when it is connected to two or more solar cells 101 in the formed solar cell module 100. The thin and planar shape of the conducting ribbons 105, which are affixed to and supported by the backsheet 103, minimizes or eliminates the chance of inducing stress in the subsequently connected solar cells 101. Conventional interconnection schemes that require the interconnecting elements to be flexed or bent to connect various regions of adjacent solar cells, will induce significant amounts of stress in the solar cells or solar cell module 100 structure, which can cause the interconnections to fail or cause the often thin solar cells 101 to fracture. In one embodiment, the conducting ribbons 105 comprise a thin soft annealed copper material that has a thickness 205 (FIG. 2B) that is between about 25 and 250 μm thick, such as about 125 μm thick. In one example, the thickness 205 of the conducting ribbons 105 is less than about 200 μm. In another example, the thickness 205 (FIG. 2B) of the conducting ribbons 105 is less than about 125 μm. As thinner conducting ribbons 105 are used in the solar cell module, the width of the formed conducting ribbon may need to increase to assure that the series resistance of the interconnect structure will not affect the solar cell module's output and overall efficiency. One will note that the stiffness of the conducting ribbons 105 in a direction normal to the surface 105E (Z-direction) varies with thickness to the third power and width to the first power, and thus reducing or minimizing the thickness will have a greater affect on the stiffness and stress generated in the formed solar cell module 100 by the conducting ribbons 105 than a proportional increase in width. In one embodiment, conducting ribbons 105 comprise a copper material that is coated with a layer of tin (Sn) to promote the electrical contact between the conducting ribbons 105 and conductive material 110, which is described below. In one embodiment, conductive ribbons 105 comprise an aluminum (Al) containing material, such as a 1000 series aluminum material (Aluminum Association designation). In some embodiments, the conductive ribbons 105 may comprise a thin base metal, such as copper (Cu) or aluminum (Al) that is coated or cladded with at least one layer of a metal selected from the group of tin (Sn), chromium (Cr), nickel (Ni), titanium (Ti), copper (Cu), silver (Ag), aluminum (Al) or other useful conductive material. In another embodiment, the conducting ribbons 105 comprise an aluminum (Al) material that is coated with a layer of nickel (Ni) or chromium (Cr). In one example, the conducting ribbons 105 are typically 6.0 mm wide, though other widths could easily be used. The conducting ribbons 105 are typically cut to a desired shape and length from a continuous roll of conducting ribbon material, and can be placed on the backsheet 103 using a pick and place robot or other similar device. One skilled in the art will also appreciate that the processes performed at step 304 avoid the issues found in the current conventional solar cell module formation processes, which require the placement of a sheet of conductive material, deposition of a masking material, etching steps to form the interconnecting elements, and then removal of the masking material. These types of conventional solar cell module formation processes are costly and are labor intensive.

In an alternate embodiment of the processing sequence 300, steps 302 and 304 are altered such that the adhesive material 104 is applied to a surface of the conducting ribbons 105 before the conducting ribbons 105 are disposed on the top surface 103A of the backsheet 103. This alternate processing configuration may be useful since it reduces the alignment and placement issues that are required when positioning the conducting ribbons 105 over the adhesive regions 104A in steps 302 and 304.

In an alternate embodiment of the processing sequence 300, the adhesive layer 104 comprises a thermoplastic material layer that is coupled to, or disposed on, the top surface 103A of the backsheet 103. In this case, the layer of the thermoplastic material can be used as an adhesive that affixes the planar conducting ribbons 105 to the backsheet 103. The process of affixing the conducting ribbons 105 to the thermoplastic material is completed by urging one or more heated conducting ribbons 105 against the thermoplastic material, thus causing the thermoplastic material to melt (i.e., ribbon temperature is greater than the melting point of the thermoplastic material), and then letting the structure cool down so that a bond is formed between the conducting ribbons 105, the thermoplastic material and the backsheet 103. This thermoplastic material would provide the encapsulation of the rear surface of the cells during lamination. Typical thermoplastics materials may include polyethylene (PE), polyolefins, EVA, or other similar thermoplastic materials.

Next, at step 306, and as shown in FIG. 2C, an optional interlayer dielectric (ILD) material 108 is disposed over the top surface 103A of the backsheet 103 and conducting ribbons 105. In one embodiment, the interlayer dielectric (ILD) material 108 is a patterned layer, or discontinuous layer, that has a plurality of vias 109, or holes, formed over a surface 105D (FIG. 2C) of the conducting ribbons 105. The patterned interlayer dielectric (ILD) material 108 can be applied to the backsheet 103 and conducting ribbons 105 using a screen printing, stenciling, ink jet printing, rubber stamping or other useful application method that provides for accurate placement interlayer dielectric (ILD) material 108 on these desired locations. In one embodiment, the interlayer dielectric (ILD) material 108 is a UV curable material that can be reliably processed at low temperatures, such as an acrylic or phenolic polymer material. In one embodiment, the interlayer dielectric (ILD) material 108 is deposited to form a thin layer that is between about 18 and 25 μm thick over the conducting ribbons 105 (e.g., thickness 208 in FIG. 2C). In this configuration, the thickness of the ILD material 108 is controlled to minimize the path length through which the generated current must pass, as it flows through the conductive material 110 (FIG. 2D) that is disposed between the conducting ribbon 105 and solar cells 101. In some configurations, the interlayer dielectric (ILD) material 108 may be deposited so that it has a thickness about the same thickness as the conducting ribbon 105 and adhesive material 104 put together, when the ILD material 108 is directly disposed on the top surface 103A of the backsheet 103. In this configuration, the deposited ILD material 108 in these regions can help support the often thin solar cells 101 during processing and during subsequent use in the field.

In some embodiments, the interlayer dielectric (ILD) material 108 may be deposited so that it covers substantially all of the exposed regions of the backsheet 103. In one example, as shown in FIG. 2H, the ILD material 108 can be used to bridge gaps 126 formed between adjacent conducting ribbons 105. In this configuration, a UV curable ILD material 108 that is deposited over the exposed regions of the backsheet 103 has some advantages, since it will absorb UV wavelengths of light, and protect the backsheet 103 from UV exposure when sunlight 127 strikes the formed solar cell module.

In some alternate embodiments, the interlayer dielectric (ILD) material 108 may be deposited on the back surface 101B of the solar cell 101 (not shown) so that it covers substantially all of the exposed regions of the solar cell except the active regions 102A and 102B. In this configuration, the placement and alignment of the ILD material 108 with the active regions 102A and 102B has some advantages, since it may provide a simpler way to assure that the openings in the ILD material are aligned with the active regions 102A and 102B when the solar cells are placed in contact with the conductive material 110 and conducting ribbons 105 in a formed solar cell module 100.

Next, at step 308, and as shown in FIG. 2D, the conductive material 110 is disposed on a surface 105E of the conducting ribbon 105 to form a plurality of conductive material regions that each interconnect portions of a solar cell 101 and a conducting ribbon 105. In one embodiment, the conductive material 110 is disposed within the vias 109 formed in the interlayer dielectric (ILD) material 108 to make contact with surface 105E of the conducting ribbon 105. The regions of conductive material 110 can be positioned in the vias 109 using a screen printing, ink jet printing, ball application, syringe dispense or other useful application method that provides for accurate placement of the conductive material 110 in these desired locations. In one embodiment, the conductive material 110 is a screen printable electrically conductive adhesive (ECA) material, such as a metal filled epoxy, metal filled silicone or other similar polymeric material that has a conductivity that is high enough to conduct the electricity generated by the formed solar cell 101. In one example, the conductive material 110 has a resistivity that is less than about 1×10⁻⁴ Ohm-centimeters.

In an alternate embodiment of step 308, the conductive material 110 is dispensed on the cell bond pads found on the back surface 101B of the solar cells 101, so that these deposited regions can then be mated with the vias 109 formed in the ILD material 108 in a later step.

In an alternate embodiment of the processing sequence 300, step 308 is merged into step 304, so that the conductive material 110 is dispensed on the surface of the conducting ribbon 105 prior to placement of the conducting ribbon 105 on the backsheet 103. This processing sequence may have advantage over other processing sequences, since it may reduce the complexity of having to align the placement of the conductive material 110 to an array of multiple conducting ribbons that are each disposed on the backsheet 103, versus the simpler task of aligning the placement of the conductive material 110 to each conducting ribbon 105 separately before placement of the conducting ribbon 105 on the back sheet 103.

Next, at step 310, a module encapsulant material 111 (FIG. 2G) is optionally disposed over the backsheet 103, interlayer dielectric (ILD) material 108 and conducting ribbons 105 to prevent environmental encroachment into the region formed between the backsheet 103 and solar cells 101. One will note that FIG. 2G illustrates an alternate embodiment of structure illustrated in FIG. 2E, which is further described below, in which a module encapsulant material 111 is disposed within the stacked assembly. The module encapsulant material is a polymeric sheet that liquefies during the subsequent lamination process to help bond the solar cells 101 to the backsheet 103. The module encapsulant material may comprise ethylene vinylacetate (EVA) or other suitable encapsulation material. The material is preferably of sufficient thickness to fill around the conducting ribbons 105 and provide a mechanical barrier between the PV cells and the conducting ribbons 105. The module encapsulant sheet is preferably cut to a size such that it extends past the edges of the backsheet. In one embodiment, prior to placement over the backsheet 103, holes are punched in the module encapsulant material to allow the conductive material 110 to extend between the solar cells 101 and conducting ribbons 105 when the cells are located thereon. The diameter of the holes is determined by the amount of area needed to form an interconnect between the conducting ribbons 105 and the conductive material 110. The process of removing the module encapsulant material to form the holes can be performed in several ways, such as a mechanical punching process or a laser ablation process. Once the module encapsulant is punched it is laid up on the backsheet 103 over the conducting ribbons 105 and registered, such that the holes in the module encapsulant line up with the vias 109 formed on the conducting ribbons 105.

At step 312, as shown in FIG. 2E, a plurality of solar cells 101 are placed over the conducting ribbons 105 to form an interconnected solar cell array 101A (e.g., FIGS. 1A, 1B). Each of the solar cells 101 are positioned so that the conductive material 110 is aligned with the solar cell's bond pads and a desirable portion of a conducting ribbon 105. In one embodiment, the solar cell bond pads are coupled to active regions 102A or 102B formed on the rear surface of a back-contact solar cell device. In one embodiment, the active region 102A is an n-type region formed in a first solar cell and the active region 102B is a p-type region formed in a second solar cell, which are connected together by a conducting ribbon 105 (FIG. 2E). In general, the active regions of the solar cell 101 are portions of the formed solar cell 101 through which at least a portion of the generated current will flow when the solar cell 101 is exposed to sunlight.

Next, at step 314, as shown in FIG. 2F, one or more enclosure components are positioned over the solar cell module 100 (e.g., reference numerals “A” and “B” in FIG. 2F), so that the whole structure can be encapsulated during a subsequent lamination process. In one embodiment, the enclosure components include a sheet of front encapsulant 115, a cover glass 116 and an optional outer-backsheet 117. The front encapsulate 115 may be similar to the module encapsulant described above, and may comprise ethylene vinylacetate (EVA) or other suitable thermoplastic material. The optional outer-backsheet 117 may comprise a sheet of polyvinyl fluoride (e.g., DuPont 2111 Tedlar™) and a thin aluminum layer, that act as a vapor and UV barrier. The aluminum layer in the outer-backsheet 117, serves primarily as a vapor barrier, is typically 35 to 50 um thick, although a thinner barrier can be used to provide better flexibility while maintain good environmental isolation. It is also possible to use a non metallic film with properties that provide for a water vapor transmission rate (WTVR) below 1×10⁻⁴ g/m²/day.

Next, at step 316, once the stack-up of the enclosure components is complete, the complete assembly (e.g., stacked assembly), is placed in a press laminator. The lamination process causes the encapsulant to soften, flow and bond to all surfaces within the package, and the adhesive material 104 and conductive material 110 to cure in a single processing step. During the lamination process the conductive material 110 is able to cure and form electrical bonds between the connection regions of the solar cells 101 and conducting ribbons 105. The lamination step applies pressure and temperature to the stacked assembly, such as the glass 116, encapsulant 115, solar cells 101, conductive material 110, conducting ribbon 105, adhesive material 104 and backsheet 103, while a vacuum pressure is maintained around the stacked assembly. In one example of a lamination process, one or more rollers (not shown) are configured to apply a pressure between about 0.1 Torr and about 10 Torr, or less than about one atmosphere (e.g., 0.101 MPa), to the stacked assembly as it is fed a rate of about 2 meters/min through the laminating device. In this example, the stacked assembly is heated to a temperature of between about 90° C. and about 165° C., while the processing environment during the lamination process is maintained a pressure below atmospheric pressure. After the lamination step, a frame is placed around the encapsulated the solar cell module for ease of handling, mechanical strength, and for locations to mount the photovoltaic module. A “junction box”, where electrical connection to other components of the complete photovoltaic system (“cables”) is made, may also be added to the laminated stacked assembly.

### Roll-to-Roll Solar Cell Module Fabrication Sequence

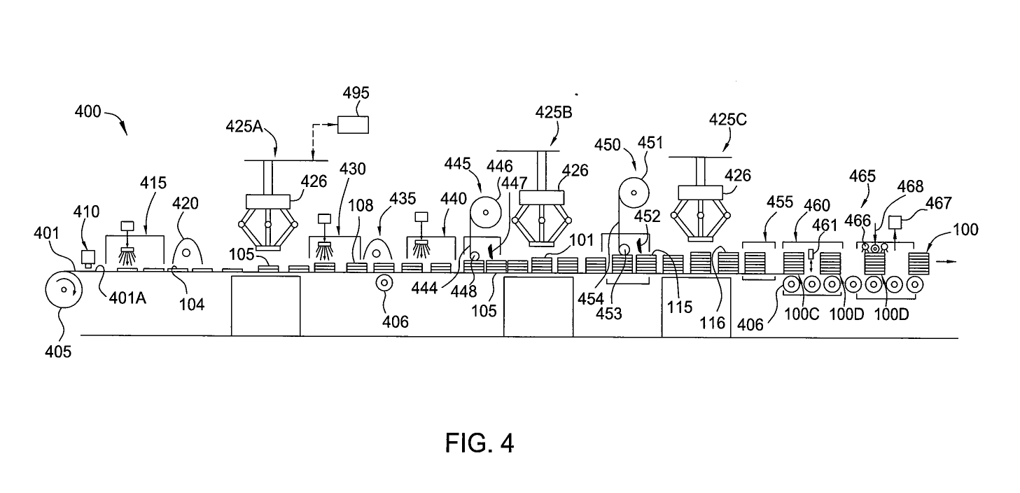

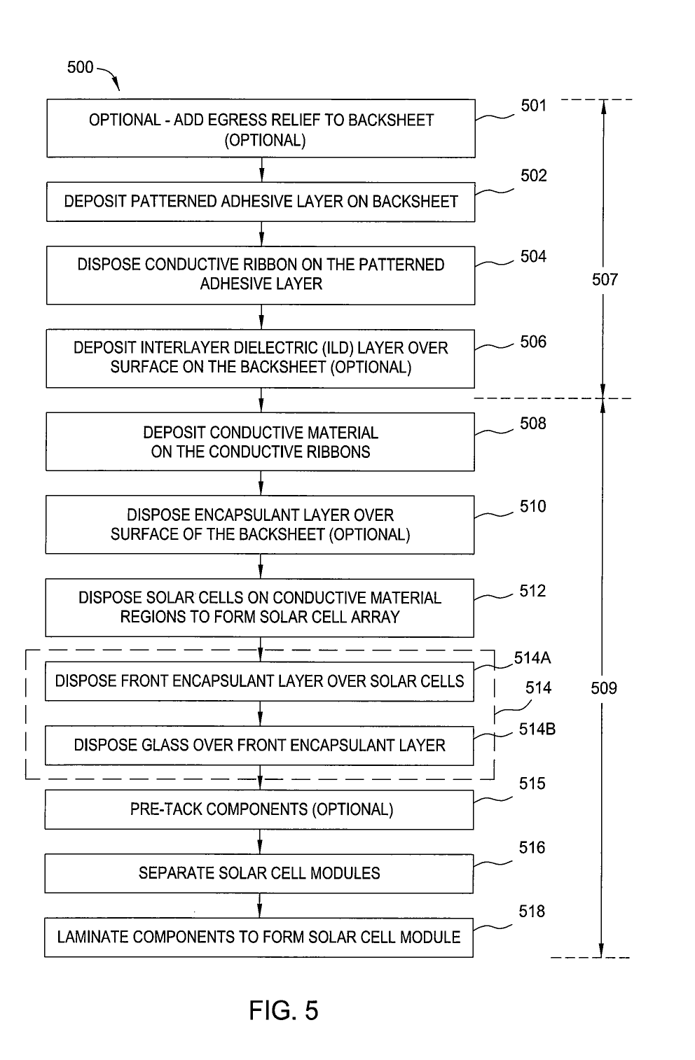

FIG. 4 is a schematic view of a roll-to-roll system 400 that is adapted to form a solar cell module 100 using a system controller 495 that is adapted to perform the processing steps found in processing sequence 500, which is illustrated in FIG. 5. The processing steps 502-518 in the processing sequence 500 may utilize one or more of the processing steps described above in conjunction with the process sequence 300.

The roll-to-roll system 400, or system 400 hereafter, is configured to receive a backsheet 401 and by performing the process steps in the processing sequence 500 to serially form a plurality of solar cell modules 100 over different portions of the backsheet 401 material. In some embodiment, the backsheet 401 material generally comprises a low cost flexible material that is rugged enough that it can effectively encapsulate and support one side of a formed solar cell module 100. The system 400 generally contains a series of processing chambers 410-465 that are configured to serially process the backsheet 401, which is generally flexible, as it is moved in a downstream direction (e.g., left-to-right in FIG. 5). In one embodiment, during normal operation, a continuous length of the backsheet 401 is delivered from a roll 405 through the processing regions of the processing chambers by use of a series of material guiding components 406 (e.g., rollers, conveyor components, motors) that are adapted to move and position the backsheet 401 within the system 400. The backsheet 401, which is similar to the backsheet 103 described above, may comprise a 100-350 μm thick polymeric material, such as polyethylene terephthalate (PET), polyvinyl fluoride (PVF), polyimide, kapton or polyethylene. In one example, the backsheet 401 is a 125-250 μm thick sheet of polyethylene terephthalate (PET). In another embodiment, the backsheet 401 comprises one or more layers of material that may include one or more layers of polymeric materials and/or one or more layers of a metal (e.g., aluminum). In one example, the backsheet 401 comprises a layer of polyethylene terephthalate (PET) and a layer of polyvinyl fluoride (PVF) that are bonded together. In another example, the backsheet 401 comprises a layer of polyethylene terephthalate (PET), a layer of polyvinyl fluoride (PVF), and a vapor barrier layer, which may comprise aluminum (Al), that are all bonded together. In yet another example, the backsheet 401 comprises a layer of a thermoplastic material, a layer of polyethylene terephthalate (PET), a layer of polyvinyl fluoride (PVF), and/or vapor barrier layer that are all bonded together. Typical thermoplastics materials, which may act as the adhesive layer 104, may include polyethylene (PE), polyolefins, EVA, or other similar thermoplastic materials. The backsheet 401, as a whole, is preferably certified to meet the IEC and UL requirements for use in a photovoltaic module.

The system 400 includes a system controller 495 that is configured to control the automated aspects of the system. The system controller 495 facilitates the control and automation of the overall system 400 and may include a central processing unit (CPU) (not shown), memory (not shown), and support circuits (or I/O) (not shown). The CPU may be one of any form of computer processors that are used in industrial settings for controlling various chamber processes and hardware (e.g., backsheet positioning components, motors, cutting tools, robots, fluid delivery hardware, etc.) and monitor the system and chamber processes (e.g., backsheet position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 495 determines which tasks are performable in the system 400. Preferably, the program is software readable by the system controller 495, which includes code to generate, execute and store at least the process recipes, the sequence of movement of the various controlled components, and any combination thereof, performed during the process sequence 500.

At step 501, and as shown in FIGS. 4 and 5, an optional egress relief (not shown) is added to the backsheet 401 in at least one location on the surface 401A by use of a conventional punch and die, cutting device or drilling device to provide an open area through the backsheet 401 into which junction box cables can eventually be positioned. The junction box cables are generally used to connect the solar cells 101 in the formed solar cell module 100 to one or more external components, such as the load “L” (FIG. 1A-1B). The egress relief may range in size from a hole that is a centimeter in diameter up-to about 3-10 centimeters in diameter or other similarly sized non-circular shape.

At step 502, and as shown in FIGS. 4 and 5, an adhesive material 104 is deposited in a desired pattern on the top surface 401A of the backsheet 401 within a module 415. In one embodiment, the deposited adhesive material 104 is disposed on the top surface 401A in a pattern to form a plurality of discrete adhesive regions, or adhesive regions 104A discussed above, by use of a screen printing, stenciling, ink jet printing, drum transfer techniques, rubber stamping or other useful application methods that provides for accurate placement of the adhesive material in the desired locations on the backsheet 401. In one embodiment, the processing steps and materials disposed on the back sheet 401 at step 502 are similar to the processing steps and materials discussed above in conjunction with processing step 302, and thus are not re-recited here.

In one embodiment of the processes performed at step 502, the deposited adhesive material 104 is at least partially cured in a processing module 420 after it is deposited on the surface 401A of the backsheet 401. The curing process may include exposing the adhesive material 104 to UV light and/or electromagnetic energy delivered from a radiant source to at least partially cure the adhesive material 104. In the case where an amount of energy is delivered to the adhesive material 104 from a radiant source, it is generally desirable to regulate the amount of energy delivered so that the temperature of the backsheet 401 and adhesive material 104 will remain below about 180° C.

Next, at step 504, and as shown in FIGS. 4 and 5, the conducting ribbons 105 are cut to a desired shape and/or length, and placed on the patterned adhesive material 104 disposed on the backsheet 401. In one embodiment, as discussed above, the conducting ribbons 105, which are affixed to and supported by the backsheet 401, have a substantially planar shape to prevent the conducting ribbons 105 from inducing stress in the subsequently attached solar cells 101 and/or interconnect structure. The process of placing the conducting ribbons 105 onto the adhesive material may include the use of robot assembly 425A that utilizes a robot 426 to place and applying pressure to the conducting ribbons 105, adhesive material 104 and backsheet 401. In one embodiment, fiducial marks formed on the surface of the backsheet 401 are used to align the conducting ribbons 105 to each other, and/or to a desired region of the backsheet 401, by use of the robot 426, optical inspection devices (e.g., CCD cameras (not shown)) and the system controller 495. The robot 426 may be a conventional robotic device, such as a SCARA robot or other similar mechanical device. In one embodiment, the processing steps and materials used to form the conducting ribbons 105 are very similar to the ones discussed above in conjunction to processing step 304, and thus are not re-recited here. In one embodiment, an automated stamping, punch and die, or similar mechanical forming device and the system controller 495 are used to cut, form or shape sheets or rolls of conductive material to form the conducting ribbons 105 prior to the conducting ribbons 105 being disposed over the adhesive material 104.

In one embodiment, step 504 may include the step of exposing regions of the adhesive material 104 that are not covered by the conducting ribbons 105, and are thus otherwise physically exposed, to electromagnetic radiation or a material curing agent to prevent the “tacky” surface of the adhesive layer 104 from attracting dirt and other contaminants and/or affecting the assembly of the solar cell module 100. In this case, the electromagnetic radiation and/or the curing agent are used to cure the exposed regions to reduce its adhesive or “tacky” nature.

At step 506, and as shown in FIGS. 4 and 5, an optional interlayer dielectric (ILD) material 108 is deposited in a desired pattern on the conducting ribbons 105 and top surface 401A of the backsheet 401 within an ILD deposition module 430. In one embodiment, the deposited interlayer dielectric (ILD) material 108 is deposited in a pattern over the conducting ribbons 105 and top surface 401A by use of a screen printing, stenciling, ink jet printing, rubber stamping or other useful application method. As noted above, in one embodiment, the interlayer dielectric (ILD) material 108 is a patterned layer, or discontinuous layer, that has a plurality of vias 109 (FIG. 2C) formed over a surface of the conducting ribbons 105. In one embodiment, the interlayer dielectric (ILD) material 108 is a UV curable material that can be reliably processed at low temperatures, such as an acrylic or phenolic material. In one embodiment, the processing steps and interlayer dielectric (ILD) material, which is disposed over the conducting ribbons 105 and top surface 401A is similar to the materials and processing steps described above in conjunction with processing step 306, and thus is not re-recited here. As noted above, in some alternate configurations, it may be desirable to deposit the ILD material on the back surface 101B of the solar cells 101 in a separate step rather than disposing it over the conducting ribbons 105 and top surface 401A.

In one embodiment of the processes performed at step 506, the deposited interlayer dielectric (ILD) material 108 is cured in a processing module 435 after it is deposited over the conducting ribbons 105 and the surface 401A of the backsheet 401. The curing process may include exposing the interlayer dielectric (ILD) material 108 to UV light and/or electromagnetic energy delivered from a radiant source. In the case where an amount of energy is delivered to the interlayer dielectric (ILD) material 108 from a radiant source, it is generally desirable to regulate the amount of energy delivered so that the temperature of the backsheet 401 and interlayer dielectric (ILD) material 108 will remain below about 180° C.

Next, at step 508, an amount of a conductive material (e.g., reference numeral 110 in FIG. 2D) is disposed on a surface of the conducting ribbon 105, using the components in a conductive material deposition module 440. In one embodiment, the conductive material 110 is disposed within the vias 109 formed in the interlayer dielectric (ILD) material 108 to make contact with surface 105E of the conducting ribbon 105. The conductive material can be positioned on the conducting ribbons 105, and/or in the vias 109, using a screen printing, ink jet printing, ball application, gravure printing process, syringe dispense or other useful application method that provides for accurate placement of the conductive material in these desired locations. In one embodiment, the conductive material is a screen printable electrically conductive adhesive (ECA) material, similar to the materials described above in conjunction with processing step 308. As noted above, in an alternate embodiment of step 508, the conductive material is dispensed on the solar cell bond pads found on the back surface of the solar cells 101, so that these deposited regions can then be mated with the surface 105E of the conducting ribbons 105 and/or the vias 109 formed in the ILD material 108 in a later step.

At step 510, a module encapsulant material 444 is optionally disposed over the backsheet 401, interlayer dielectric (ILD) material 108 and conducting ribbons 105 while it is disposed in an encapsulant deposition module 445. The module encapsulant material 444, which is similar to the module encapsulant material discussed above in conjunction with step 310, and is generally used to prevent environmental encroachment into the region formed between the backsheet 401 and solar cells 101 during the normal operation of the formed solar cell module 100. As discussed above, the module encapsulant material is generally a polymeric sheet that may comprise ethylene vinylacetate (EVA) or other suitable encapsulation material. In one embodiment, the module encapsulant material 444, which is delivered from a roll 446, is disposed over the backsheet 401, interlayer dielectric (ILD) material 108 and conducting ribbons 105 by use of a roller 448 and sectioning device 447 that are able to dispose a sheet of the module encapsulant material 444 thereon. In one embodiment, prior to placement over the backsheet 401, holes are punched into the module encapsulant material 444 by automated machine components (not shown) disposed in the encapsulant deposition module 445 to provide openings through which the conductive material 110 is able to contact a solar cell 101 and a conducting ribbon 105. The process of forming holes in the module encapsulant material can be performed in several ways, such as a mechanical punching process or a laser ablation process. During step 510, the module encapsulant is positioned on the backsheet 401 over the conducting ribbons 105 and is registered, such that the holes formed in the module encapsulant 444 line up with the vias 109 formed the ILD material 108.

Next, at step 512, a plurality of solar cells 101 are placed over the conducting ribbons 105 to form an interconnected solar cell array (e.g., reference numeral 101A in FIGS. 1A-1B) that is disposed over the top surface 401A of the backsheet 401. Each solar cell 101 in the solar cell array is positioned so that the deposited conductive material 110 is aligned with the solar cell bond pads, or electrical connection points, and portions of a desired conducting ribbon 105. In one embodiment, the active region 102A is an n-type region formed in a first solar cell and the active region 102B is a p-type region formed in a second solar cell that are connected together by a conducting ribbon 105 (FIG. 2E). The process of placing the solar cells 101 over the top surface 401A of the backsheet 401 and ribbons 105, will generally include the use of a robot 426 found in a robot assembly 425B. The robot 426 is used to position and applying pressure to the solar cell 101, conductive material 110, conducting ribbon 105 and backsheet 401 to form an interconnection between other positioned solar cells 101. The robot 426 found in the robot assembly 425B may be a convention robotic device, such as discussed above. In one embodiment, fiducial marks formed on the backsheet 401 are used to align the solar cells 101 to each other, and/or to desired regions of the conducting ribbons 105, by use of the robot 426, optical inspection devices (not shown) and the system controller 495.

Next, at step 514, as shown in FIG. 4, one or more enclosure components are positioned over the solar cell module 100, so that the whole structure can be encapsulated during a subsequent lamination process. In one embodiment, the formation of the encapsulated solar cell array is performed by use of two processing steps 514A and 514B (FIG. 4), which are discussed below.

In the first step, or step 514A, a front encapsulant material 454 is disposed over the backsheet 401, conducting ribbons 105, interlayer dielectric (ILD) material 108 and solar cells 101, while these components are disposed in an encapsulant deposition module 450. The front encapsulant material 454 is similar to the front encapsulant 115 discussed above in conjunction with step 314. As discussed above, the front encapsulant material is generally a polymeric sheet that may comprise ethylene vinylacetate (EVA) or other suitable encapsulation material. In one embodiment, the front encapsulant material 454, which is delivered from a roll 451, is disposed over the backsheet 401, conducting ribbons 105, interlayer dielectric (ILD) material 108 and solar cell 101 by use of a roller 453 and sectioning device 452 that are able to dispose a sheet of the front encapsulant material 454 thereon. During step 514A, the front encapsulant material 454 is positioned so that it covers the entire solar cell array 101A to assure that the solar cell array will be encapsulated in the subsequent lamination step. In one embodiment, fiducial marks formed on the backsheet 401 are used to align the sheet of front encapsulant material 454 to the backsheet 401, by use of one or more encapsulant deposition module 450 components, optical inspection devices (not shown) and the system controller 495.

In the next step, or step 514B, a cover glass 116, which may act as a protective sheet or layer, is disposed over the front encapsulant material 454 by use of a robot 426 found in a robot assembly 425C. The process of placing the cover glass 116 over the front encapsulant material 454, will generally include positioning the sheets of precut cover glass 116 over the front encapsulant material 454 by use of the robot 426. The robot 426 found in the robot assembly 425C is generally a convention robotic device, such as discussed above. During step 514B, the cover glass is positioned so that it covers the entire solar cell array 101A to form a stacked assembly 100C, and assure that the solar cell array will be fully covered when processed in the subsequent lamination step. In one embodiment, fiducial marks formed on the backsheet 401 are used the align of the cover glass 116 to a desired region of the backsheet 401 by use of the robot 426, optical inspection devices (not shown) and the system controller 495.

At step 515, once the stack-up of the enclosure components is complete, the stacked assembly 100C (FIG. 4) may be optionally “pre-tacked” in a process module 455 to assure that each component in the stacked assembly will remain in correct alignment while it is positioned and oriented for the subsequent lamination process. During the pre-tacking process the assembly is exposed to electromagnetic energy delivered from a radiant source (not shown) to cause at least a portion of the encapsulant material(s) to soften and bond all of the components in the stacked assembly 100C together. In one example, the pre-tack process includes heating the stacked assembly 100C (FIG. 4) to a temperature between about 90° C. and about 150° C., for example, between about 90° C. and about 125° C. In one example, the pre-tack process includes heating various portions of the stacked assembly 100C using a laser or other focused energy emitting device.

At step 516, each of the formed stacked assemblies 100C are separated from each other by use of a sectioning device 461 that is disposed in a sectioning module 460. The sectioning device 461 is generally an automated or semi-automated mechanical cutting device that is able to cut through the backsheet 401 to form a separated stacked assembly 100D, which comprises the components disposed over the remaining portion of the backsheet 401 during one or more of the process steps 501-515. In one embodiment of the processing sequence 500, the separation of the stacked assemblies 100C from the other connected stacked assemblies 100C is performed after the lamination step (step 518) has been performed.

Next, at step 518, once the stack-up of the enclosure components is complete, the separated stacked assembly 100D is placed in a press laminating device 465. The lamination process causes the encapsulant material(s) to soften, flow and bond to all surfaces with in the package, and the adhesive material 104 and conductive material 110 to cure in a single processing step. As noted above, in some embodiments, during the lamination process the conductive material 110 is able to cure and form electrical bonds between the connection regions (e.g., bond pads) of the solar cells 101 and conducting ribbons 105. The lamination step applies pressure and temperature to the separated stacked assembly 100D, while a vacuum pressure is maintained around the stacked assembly. In one example of a lamination process, one or more rollers 468 are configured to apply a pressure less than about one atmosphere of pressure to a separated stacked assembly 100D that is fed a rate of about 2 meters/min through the laminating device 465. In this configuration, the separated stacked assembly 100D is heated to a temperature of about 105° C. and about 250° C. using a conventional heat source, while the processing environment during the lamination process is maintained a pressure of between about 0.1 Torr and about 10 Torr by use of mechanical pump 467 (e.g., mechanical rough pump). After the lamination step, a frame is placed around the encapsulated the formed solar cell module 100, such as solar cell module 100A, 100B, for ease of handling, mechanical strength, and for locations to mount the photovoltaic module. A “junction box”, where electrical connection to other components of the complete photovoltaic system (“cables”) is made, may also be added to the laminated stacked assembly.

In one embodiment, the processing sequence 500 is divided into two groups of processing steps, the front-end processing steps 507 and the back-end processing steps 509 (FIG. 5). The front end processing steps 507, or generally steps 501-506, may be performed on the backsheet 401 in a separate area of the solar cell fabrication facility, in a separate fabrication facility, or by an outside vendor, and then rolled-up to form an intermediate fabrication roll, which can be later used in a fabrication sequence that is adapted to perform the back-end processing steps 509. In one embodiment, the intermediate fabrication roll comprises the backsheet 401, adhesive regions 104A and conducting ribbons 105. In another embodiment, the intermediate fabrication roll comprises the backsheet 401 and one or more of the following elements: egress relief formed in the backsheet 401, adhesive regions 104A, conducting ribbons 105, and an ILD material 108. In one embodiment, the front end processing steps 507 only include steps 501-504 and the back-end processing steps 509 include steps 506-518.

In one embodiment, the back-end processing steps 509, or generally steps 508-518, begins by receiving the material found in the intermediate fabrication roll, and then performing one or more processing steps on the material to form a plurality of solar cell modules 100. In one embodiment, the back-end processing steps 509 comprise processing steps 508, 512, 514, 516 and 518, which are discussed above. In another embodiment, the back-end processing steps 509 comprise steps 508 and 512, and one or more of the processing steps 510, 514, 515, 516 and 518, which are discussed above. In an alternate embodiment, the back-end processing steps 509, begin by receiving discrete sections of the intermediate fabrication roll, and then performing one or more processing steps on each discrete section to form a plurality of solar cell modules 100. In this alternate configuration, a sectioning device 461 may be used after performing step 506 to form the discrete sections that are later used in the back-end processing steps 509.

In one embodiment of the processing sequence 500, the module encapsulant material 444 deposition process, or step 510, is performed before the conductive material 110 is disposed on the conducting ribbon 105, or before processing step 508 is performed. Therefore, in one embodiment of the processing sequence 500, the front-end processing steps 507 can be used to form an intermediate fabrication roll that comprises the backsheet 401 and one or more of the following elements: egress reliefs formed in the backsheet 401, deposited adhesive regions 104A, conducting ribbons 105, an ILD material 108 and the encapsulant material 444. In this example, the module encapsulant material 444 will have a plurality of holes formed therein to allow each of later deposited regions of conductive material 110 to contact a surface of the conducting ribbons 105 and a solar cell bond pad formed on a surface of a solar cell 101.

One will note that a non-roll-to-roll type solar cell module processing sequences may also benefit from a divided processing sequence. Therefore, in cases where processing sequence 300 is utilized to form solar cell modules 100 from discrete sheets of backsheet material, the processing sequence can be divided into front-end processing steps, such as steps 302-306, and back-end processing steps, such as steps 308-316. In this case, the front-end processing steps may be performed by in a separate area of the solar cell fabrication facility, in a separate fabrication facility, or by an outside vendor.

One advantage of this construction method is that it uses commercially available materials and processes while avoiding the problems associated with conventional PV module assembly processes. The cells are planar with no ribbon passing between the top and bottom surfaces of the cell. This allows the cells to be placed closer together while avoiding stressing the portions of the solar cell where ribbon passes from the top of one cell to the bottom of another solar cell. The planar construction of the solar cell module also provides for lower mechanical stresses during normal thermal cycling, which the solar cell module will undergo on a daily basis when installed in the field.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference. The advantages of solar cell module described herein include the following. First, a single thermal processing step, or lamination step, is used to encapsulate the solar cell module to reduce the number of processing steps and reduce the solar cell manufacturing cost. Second, the planar geometry of the formed solar cell module is easier to automate, which reduces the cost, and improves the throughput of the production tools, while also introducing less stress in the formed device and enabling the use of thin crystalline silicon solar cells. Third, a smaller spacing between solar cells may be used compared to conventional photovoltaic modules with copper ribbon interconnects, which increases the module efficiency and reduces the solar cell module cost. In some configurations, the copper busses at the end of the modules can also be reduced or eliminated, which also reduces module size for reduced cost and improved efficiency. Fourth, the number and location of the contact points formed on a solar cell can be easily optimized since the geometry is only limited by the patterning technology. This is unlike stringer/tabbers designs where additional copper interconnect straps or contacting points increase cost. The net result is that the cell and interconnect geometry can be more easily optimized with monolithic module assembly. Fifth, the electrical circuit on the backsheet can cover nearly the entire surface. The conductivity of the electrical interconnects can be made higher because the effective interconnect is much wider. Meanwhile, the wider conductor can be made thinner (typically less than 50 μm) and still have low resistance. A thinner conductor is more flexible and reduces stress. Finally, the spacing between solar cells can be made small since no provision for stress relief of thick copper interconnects is needed. This improves the module efficiency and reduces the module material cost (less glass, polymer, and backsheet due to reduced area).

While the foregoing is directed to embodiments of the present invention, other and further embodiments of the invention may be devised without departing from the basic scope thereof, and the scope thereof is determined by the claims that follow.

1. A solar cell module assembly, comprising:
a flexible backsheet having a mounting surface;
a patterned adhesive layer comprising a plurality of adhesive regions that are disposed on the mounting surface; and
a plurality of conducting ribbons, wherein a first surface of each of the conducting ribbons is disposed on at least one of the plurality of adhesive regions, and each of the plurality of conducting ribbons are substantially planar and are non-linear relative to a plane that is substantially parallel to the mounting surface.

2. The solar cell module of claim 1, wherein the backsheet comprises two or more polymeric containing layers that are selected from a group that comprises polyethylene terephthalate (PET), polyvinyl fluoride (PVF), polyimide, kapton, polyethylene and polyolefin.

3. The solar cell module of claim 1, further comprising:
a plurality of solar cells that are disposed over the conducting ribbons to form an interconnected solar cell array, wherein each of the plurality of solar cells is electrically connected to a portion of one of the plurality of conducting ribbons by use of a conductive material.

4. The solar cell module of claim 3, further comprising:
a patterned interlayer dielectric material disposed between the conducting ribbon and the plurality of solar cells.

5. The solar cell module of claim 1, wherein the patterned adhesive layer is substantially covered by the plurality of conducting ribbons.

6. The solar cell module of claim 1, wherein the backsheet comprises a material selected from a group consisting of polyethylene terephthalate (PET), polyvinyl fluoride (PVF) and polyethylene.

7. The solar cell module of claim 1, wherein the plurality of conducting ribbons comprise a first metal layer that comprises copper or aluminum, and a second metal layer that comprises aluminum, copper, nickel, tin or chrome, wherein the first and second metal layers are not formed from the same metal.

8. A method of forming a solar cell device assembly, comprising:
positioning a plurality of conducting ribbons over a mounting surface of a flexible backsheet, wherein an adhesive region is disposed between the mounting surface and a first surface of each of the plurality of conducting ribbons, and each of the plurality of conducting ribbons are substantially planar and are non-linear relative to a plane that is substantially parallel to the mounting surface.

9. The method of claim 8, wherein disposing the adhesive region over the mounting surface comprises forming a patterned adhesive layer on the mounting surface.

10. The method of claim 9, wherein the first surface of each of the plurality of conducting ribbons substantially covers the adhesive region.

11. The method of claim 9, wherein the patterned adhesive layer is applied to the mounting surface by a screen printing, drum rolling or ink jet printing process.

12. The method of claim 8, further comprising curing portions of the adhesive regions that are not covered by each of the plurality of conducting ribbons after the plurality of conducting ribbons are positioned over the mounting surface.

13. The method of claim 8, further comprising depositing a plurality of adhesive regions on the mounting surface of the backsheet before positioning the plurality of conducting ribbons over the mounting surface.

14. The method of claim 8, further comprising:
depositing a patterned interlayer dielectric layer over a second surface of the plurality of conducting ribbons and the mounting surface, wherein the patterned interlayer dielectric layer has one or more vias that are formed over the second surface of each of the plurality of conducting ribbons.

15. The method of claim 14, further comprising depositing a conductive material in each of the formed vias formed over the second surface of the conducting ribbons.

16. The method of claim 8, further comprising:
depositing a conductive material on a second surface of the plurality of conducting ribbons, wherein the deposited conductive material is disposed in one or more conductive material regions disposed on each of the plurality of conducting ribbons; and
positioning a plurality of solar cells over the deposited conductive material, wherein an active portion of each positioned solar cell is in electrical communication with one of the one or more conductive material regions and one of the plurality of conducting ribbons.

17. The method of claim 16, further comprising:
disposing an encapsulant and a protective sheet over the plurality of solar cells; and
laminating the protective sheet and encapsulant to the plurality of solar cells, wherein the process of laminating the protective sheet and encapsulant to the plurality of solar cells substantially cures the patterned adhesive layer.

18. The method of claim 16, wherein each of the plurality of conducting ribbons is coupled to an n-type region formed in a first adjacent solar cell and a p-type region in a second adjacent solar cell.

19. A method of forming a solar cell device assembly, comprising:
depositing a conductive material on a plurality of planar shaped conducting ribbons that are disposed on a portion of a flexible backsheet that is disposed in a first processing region of a system, wherein the conductive material is disposed on one or more conductive material regions on a first surface of each of the plurality of planar shaped conducting ribbons;
transferring the portion of the flexible backsheet to a second processing region of the system that is downstream of the first processing region;
positioning a plurality of solar cells over the deposited conductive material to form an array of interconnected solar cells in the second processing region of the system, wherein an active portion of each positioned solar cell is in electrical communication with one of the one or more conductive material regions and one of the plurality of planar shaped conducting ribbons;
positioning an encapsulant material over the array of interconnected solar cells disposed over the portion of the backsheet;
positioning a protective sheet over the encapsulant material;
heating the portion of the backsheet material, plurality of planar shaped conducting ribbons, encapsulant material and protective sheet to form a bond therebetween in a third processing region of the system that is downstream of the second processing region; and
cutting a portion of the flexible backsheet material to separate the portion of the flexible backsheet material from other portions of the flexible backsheet material.

20. The method of claim 19, wherein depositing the conductive material on the plurality of planar shaped conducting ribbons further comprises:
positioning a plurality of conducting ribbons over a mounting surface of the flexible backsheet before depositing the conductive material on the plurality of planar shaped conducting ribbons, wherein an adhesive region is disposed between the mounting surface and a second surface of each of the plurality of planar shaped conducting ribbons, and each of the conducting ribbons are substantially planar and are non-linear relative to a plane that is substantially parallel to the mounting surface.

21. The method of claim 19, further comprising:
depositing a patterned interlayer dielectric layer over the conducting ribbons and a mounting surface of the flexible backsheet before depositing the conductive material on the first surface of the planar shaped conducting ribbons, wherein the patterned interlayer dielectric layer has one or more vias formed over each of the planar shaped conducting ribbons; and
the depositing the conductive material on the first surface of the conducting ribbons further comprises disposing a conductive material region in each of the formed vias.

22. The method of claim 19, wherein positioning the encapsulant material and the protective sheet over the plurality of solar cells further comprises:
receiving a portion of an encapsulant material from a roll of encapsulant material;
cutting the encapsulant material to separate the portion of the encapsulant material from other portions of the encapsulant material; and then
positioning the portion of the encapsulant material over the plurality of solar cells.
